(19) United States
(12) Patent Application Publication
(10) Pub. No.: US 2010/0272294 A1
(43) Pub. Date: Oct. 28, 2010

(54) TWO-CHANNEL AMPLIFIER WITH COMMON SIGNAL

(75) Inventors: Lars Arknaes-Pedersen, Viby J (DK); Kim Rishoj Pedersen, Ega (DK)

Correspondence Address: CANTOR COLBURN, LLP, 20 Church Street, 22nd Floor, Hartford, CT, 06103, US

(73) Assignee: THE TC GROUP A/S, Risskov (DK)

(21) Appl. No.: 12/809,767

(22) PCT Filed: Dec. 21, 2007
(86) PCT No.: PCT/DK2007/050204

§ 371 Date: Jun. 21, 2010

(51) Int. Cl. H03F 99/00; H03F 3/45

(52) U.S. Cl. 381/120; 330/69

(57) ABSTRACT

A two-channel amplifier with common signal including a splitter for establishing three intermediate signals on the basis of two input signals, wherein the three intermediate signals represent two channels, one of the three intermediate signals being a common signal common to both of the two channels and having a representation based on a sum of the two input signals.

### TECHNICAL FIELD

The present invention relates to amplification of stereo signals for 3-wire outputs, e.g. for conventional headphones.

### BACKGROUND

A main aim when designing an amplifier system is to optimize power output for a given voltage supply, in particular when voltage supply is not unlimited.

Conventionally, the best way to operate an amplifier when optimizing for power output has been to use a bridged output coupling. Thereby potentially twice the supply voltage swing on the speaker terminal can be achieved. However, such amplifiers requires two wires for each speaker, so-called double differential pair DDP, in order to be able to push the voltage on one wire and simultaneously pull the voltage on the other, to potentially achieve a peak-peak value corresponding to twice the peak-peak value of the supply voltage.

Most headphones, however, are only provided with one distinct wire for each speaker, and a common wire to close the circuits. I.e., the stereo signal has to travel through 3 wires, leaving no chance of using a bridged stereo signal as described above, since this requires 4 wires in a double differential pair DDP coupling.

Some mixed solutions exist, where the phase of one of the speakers is reversed, and the difference of the two channels is delivered to the common wire. Three half-bridges, i.e. single-ended output amplifiers, are used for amplifying e.g. the left channel L, the reversed right channel −R and the difference signal L−R. When rendered by the speakers, the right speaker will reproduce L−(L−R)=R, and the left speaker will reproduce (L−R)−(−R)=L. Although such methods allow for bridged amplification and utilizing the common wire, they are encumbered with problems and non-optimal performance. One problem for example comprises the requirement of one speaker being reversed, which requires headphones produced especially for such an amplifier, useless in other amplifiers, or the user to re-solder the wiring himself One example of the method being non-optimal is that it does not allow for twice the supply voltage swing for each channel as explained above for a DDP-amplifier, when the left and right channels are approaching an in-phase situation, as the common signal will then approach zero (L≈R [symbol] L−R≈0). It is a fact that for most typical music, the left and right channels are in-phase, at least in the high energy carrying lower frequency bands, thereby causing the methods with one channel reversed and a difference signal on the common wire to yield in practice only insignificant extra power.

Another existing solution applies only to time-division multiplexed PWM stereo signals, where the two channels are never active simultaneously, but when a channel is active, it uses two conductors for information. A simple configuration using OR-gates maps the four conductors, whereof only two are active at a time, to the three conductors in a conventional headphone configuration, by ensuring that the inactive channel is provided with a signal that is cancelled by the common signal. Three half-bridge amplifiers are provided for amplifying the three signals for the headphone. Besides only being applicable to the above-mentioned quite specialized audio signal representation, this solution is very inferior when it comes to power efficiency, as the loads are only active for less than half of the time even for full-scale signals, and because even the amplifier in the inactive channel is employed to establish a cancelling signal. A solution according to this will not be able to provide a signal voltage swing greater than the supply voltage swing.

The invention seeks to achieve a two-channel amplifier that delivers a two-channel signal with a common wire, but which also benefits at least partially from the potential twice the supply voltage swing obtainable by bridged configurations. In other words, the present invention desires to obtain a stereo amplifier which to some extent benefits from the advantages of bridged amplifiers, but with a common wire.

### BRIEF SUMMARY

The present invention relates to a two-channel amplifier with common signal comprising a splitter SPL for establishing three intermediate signals X, Y, Z on the basis of two input signals LI, RI, wherein said three intermediate signals X, Y, Z represent two channels, one of said three intermediate signals being a common signal Z common to both of said two channels and comprising a representation based on a sum of said two input signals LI, RI.

The present invention facilitates a significant cost-efficiency increase for amplifiers not possible to implement with two pairs of individual signals, e.g. because the output has to be transmitted through a 3-wire stereo headphone cable with a jack plug interface. Such a two-channel amplifier with a 3-wire output can now, because of the present invention, be build using a half-bridge or single-ended output amplifiers for each of all three signals involved instead of only for the two channel-specific signals. Thereby is among other things enabled benefitting at least partially from the potential twice the supply voltage swing, which has so far been reserved conventional bridged, double differential pair configurations, which as explained above, are unusable for driving 3-wire outputs, e.g. stereo headphone outputs. In other words, it is possible by means of the present invention to obtain a stereo amplifier which to a significant extent benefits from the advantages of bridged amplifiers but with a common wire, which enables use in consumer electronics and other devices where 3-wire stereo connections are commonly used, e.g. the widespread stereo jack and stereo mini-jack plugs used in headphones, headsets, portable audio devices, e.g. MP3-players, mobile phones, etc., cameras, amplifiers, line connections, desktop computers, laptops, etc.

The concept underlying the present invention involves the fact that it has proven possible by the inventors to map two signals, e.g. a left and right signal, into the 3 wires available in the above-mentioned devices, so the full advantage of bridged amplifier design can be obtained when the signals are in-phase and fortunately almost all music sources have their main energy in the bass which more or less always is in-phase. In practice, the parts of the signals that are not equal will reduce the advantage to a certain extent, but still the present invention is significantly advantageous over conventional amplifiers for 3-wire outputs, typically amplifiers where the common wire is simply grounded. The present invention utilizes the fact that sums of substantially in-phase signals fairly well represent the signals, even at an increased level, whereas earlier suggestions for amplifiers with common signals have used difference signals, which fairly well eliminates any in-phase information and thereby the music.

Using popular music produced and mixed using standard procedures, which is what most of the above-mentioned devices by millions of people are put to use for, the principle has a very big advantage when talking of power output as function of supply voltage. And exactly supply voltage is an important issue for most audio consumer electronics, as it is typically driven by batteries from which longer endurance and higher power output is always desired. Looking at the statistics, even with quite aggressively mastered music such as e.g. Madonna's “Confessions on a Dance Floor”, a preferred embodiment of the present invention involves only audio quality problems at extremely high volume settings for signal levels above between −2 dBFS and −1 dBFS. As a preferred embodiment of the present invention in theory achieve a 6 dB increase in the power provided to the load, e.g. a pair of headphones, the embodiment of the present invention still have approx. 4 dB level advantage, i.e. more than double power, compared to ordinary headphone amplifiers.

The present invention further comprises ways of reducing the distortion applied to the very small part of the signals that have very high levels, so the advantage is maintained without reduction of audio quality.

The present invention may be implemented for any kind of paired signals, typically audio stereo signals, i.e. any representations of analog and digital signals. The splitter is preferably digitally implemented, e.g. in a microprocessor, digital signal processer DSP or e.g. a field programmable gate array FPGA, but may be implemented by any means, including analog means, enabling implementation of the splitting algorithm. In a preferred embodiment the input signal representation, the splitter and the subsequent amplifiers all belong to the same domain, preferably the digital domain.

According to the present invention, a common signal based on a sum of the input signals may evidently comprise simply a sum of the input signals, but the sum may also be subject to further pre- or post-processing, e.g. multiplication, division, inversion, further addition, subtraction, extrapolation, etc. In a preferred embodiment of the present invention the common signal is for example based on a sum of the input signals, which are further halved and inverted.

When the two-channel amplifier with common signal comprises two inputs for receiving said two input signals LI, RI, three outputs for providing three output signals A, B, C and an amplifier block AMP for establishing said three output signals A, B, C on the basis of said three intermediate signals X, Y, Z, an advantageous embodiment of the present invention is obtained.

According to an embodiment of the present invention, an amplifier block is provided for amplifying the three intermediate signals. The greatest advantage of the present invention is obtained when amplification is needed, and the splitting performed prior to amplification. The three outputs may comprise any interface for providing a S-wire two-channel signal, typically a stereo jack or mini-jack sockets, but any other interfaces are within the scope of the present invention, including RCA sockets, etc. The two inputs may be internal wiring, registers or memory inside the device, e.g. to enable communication between an audio decoder and the amplifier of the present invention, e.g. in a portable audio device, or they may comprise any interface for providing a two-channel signal, typically at line level, e.g. RCA sockets, independent mono jack sockets, XLR sockets, optical interfaces, wireless interfaces, etc.

The amplifier block may according to the present invention comprise any kind and configuration of amplifiers. The amplifier block preferably comprises three class-D single-ended half-bridge output amplifiers, one for each of the intermediate signals, but any means for amplifying the intermediate signals are within the scope of the present invention, including conventional all-analog amplifiers, other digital or semi-digital amplifiers, etc.

When said amplifier block AMP comprises three single-ended output amplifiers, an advantageous embodiment of the present invention is obtained.

When said amplifier block AMP is driven by a double-sided power supply, an advantageous embodiment of the present invention is obtained.

According to an embodiment of the present invention a double-sided power supply, i.e. a power supply with a positive and negative supply voltage, is used. This enables amplification of signals comprising both positive and negative values.

When said amplifier block AMP is driven by a single-sided power supply, an advantageous embodiment of the present invention is obtained.

According to an embodiment of the present invention a singe-sided power supply, i.e. a power supply with only a positive supply voltage and ground, is used. Even though this embodiment does not enable immediate amplification of signals with both positive and negative values, it is a preferred embodiment because most portable, battery-driven devices provide only a single-side power supply, i.e. the battery. In a preferred embodiment, an further step of adapting the intermediate signals into only comprising positive values is applied prior to amplification.

When the two-channel amplifier with common signal comprises a level setting input LS, an advantageous embodiment of the present invention is obtained.

A level setting input according to the present invention may e.g. comprise a control input for gain control of the input or intermediate signals. The level setting input may refer to a physical input for a user to take control, or an internal input for a control block to take control. It is noted that the level settings may also be controlled by e.g. the splitter or amplifier itself, thereby leaving a level setting input optional.

When the two-channel amplifier with common signal comprises a dynamic setting input DS, an advantageous embodiment of the present invention is obtained.

A dynamic setting input according to the present invention may e.g. comprise a control input for controlling e.g. limiting, compression or other dynamics processing of the input or intermediate signals. The dynamic setting input may refer to a physical input for a user to take control, or an internal input for a control block to take control. It is noted that the dynamics settings may also be controlled by e.g. the splitter or amplifier itself, thereby leaving a dynamic setting input optional.

When said two input signals LI, RI represent a left channel and a right channel, respectively, of a stereo audio signal, an advantageous embodiment of the present invention is obtained.

When said three outputs are arranged for connecting two loads LHP, RHP, preferably headphones, by connecting one of said three output signals being a common output signal C common to both of said two channels to both of said two loads, and connecting each of other two of said three output signals A, B to corresponding ones of said two loads, respectively, an advantageous embodiment of the present invention is obtained.

A great advantage of the present invention compared with other suggested solutions is that is enables use of completely ordinary headphones, loudspeakers or other loads. In other words, all the extraordinary processing and configurations necessary to achieve the benefits of the present invention are placed in the two-channel amplifier of the present invention itself The inputs and outputs of a preferred two-channel amplifier according to the present invention require no extraordinary configurations, but simply connect with conventional products, e.g. conventional 3-wire headphones with a jack-plug. Evidently, each load requires two wires, and two loads therefore require four wires, but the common configuration used in conventional headphones, etc., for reducing this to three wires in the connection cable, is fully compatible with the outputs of the present invention.

When said common signal Z comprises a representation of half an inverse sum of said two input signals LI, RI, an advantageous embodiment of the present invention is obtained.

As the two signals in stereo music, at least for the lower frequencies, are typically substantially in phase, a sum of such simply resemble any one of the signals, but at twice the level. In a preferred embodiment, the sum is therefore halved, and inverted because it is provided to the negative load connector. It is noted that any suitable algorithm for establishing the common signal is within the scope of the present invention.

When a second of said three intermediate signals X comprises a sum based on a first of said two input signals LI and said common signal Z, and a third of said three intermediate signals Y comprises a sum based on a second of said two input signals RI and said common signal Z, an advantageous embodiment of the present invention is obtained.

In order to produce sound in a headphone provided with an information carrying common signal at the negative connector, the positive connector has to be provided with a signal resembling the sum of the common signal and the desired signal. i.e. LHP=A−C=g·LI [symbol] A=C+g·LI. Therefore the intermediate signals X and Y may be established as Z+LI and Z+RI, respectively.

When said second of said three intermediate signals X comprises a signal corresponding to a sum of said common signal Z and a factor k times a first of said two input signals LI, and said third of said three intermediate signals Y comprises a signal corresponding to a sum of said common signal Z and said factor k times a second of said two input signals RI, an advantageous embodiment of the present invention is obtained.

In a preferred embodiment, the intermediate signals X and Y are based on scaled representations of the input signals. Hence, they may e.g. be established as Z+k·LI and Z+k·RI, respectively. The factor k controls the gain advantage obtained compared with ordinary headphone amplifiers.

When said factor k substantially equals 2, an advantageous embodiment of the present invention is obtained.

In a preferred embodiment the factor k is 2, whereby is obtained an advantage corresponding to the advantage of bridged output amplifier e.g. with double differential pairs connections, and still the possible distortion is insignificant. A further increase of the factor k drastically increases the distortion.

When said factor k is controlled by said level setting input LS, an advantageous embodiment of the present invention is obtained.

When adaptive limiting or soft limiting is applied to said three intermediate signals, an advantageous embodiment of the present invention is obtained.

In order to avoid hard clipping due to overload and restricted dynamic range, a preferred embodiment of the present invention comprises controlled limiting. Any way of limiting the clipping error is within the scope of the present invention.

When said limiting is controlled by said dynamic setting input DS, an advantageous embodiment of the present invention is obtained.

When the two-channel amplifier with common signal comprises a processing block PC adapting said three intermediate signals X, Y, Z into three positive only signals a, b, c; A, B, C, an advantageous embodiment of the present invention is obtained.

In order to be able to use the present invention with single-sided power supplies, e.g. batteries, the signals to be amplified have to comprise only positive values. A preferred embodiment of the present invention therefore comprises a processing block for adapting the three intermediate signals into three positive-only signals prior to amplification.

When said three positive-only signals a, b, c; A, B, C comprise half the differences between said three intermediate signals X, Y, Z and a minimum value LV across said three intermediate signals X, Y, Z, respectively, an advantageous embodiment of the present invention is obtained.

Any method of adapting a signed signal into a positive-only signal is within the scope of the present invention. A preferred method comprises finding the minimum value across the three signals and subtracting this from all the signals. Thereby the level of the minimum signal level is increased or decreased to zero, and the other signals moved by the same off-set. Thereby the differences between the two individual signals and the common signal are maintained, and thus no distortion applied, the levels are simply shifted by a common offset.

When a clamping value MV is added to each of said three positive-only signals a, b, c; A, B, C, an advantageous embodiment of the present invention is obtained.

Any method of avoiding non-linearity problems in the amplifiers is within the scope of the present invention. A preferred embodiment comprises adding a clamping value, e.g. corresponding to the lowest value for which a correct pulse can be produced by a class-D amplifier, to the signals.

When the two-channel amplifier with common signal comprises a clamper setting input CS controlling said clamping value MV, an advantageous embodiment of the present invention is obtained.

When soft limiting or adaptive limiting is applied to said three positive-only signals a, b, c; A, B, C, an advantageous embodiment of the present invention is obtained.

When the two-channel amplifier with common signal comprises a dynamics setting input DS controlling said limiting, an advantageous embodiment of the present invention is obtained.

When the two-channel amplifier with common signal comprises an input for a single-sided power supply, preferably a battery, an advantageous embodiment of the present invention is obtained.

When the two-channel amplifier with common signal comprises an input for a double-sided power supply, an advantageous embodiment of the present invention is obtained.

When the two-channel amplifier with common signal comprises processing means for avoiding substantially concurrent edges of pulse width modulated signals, an advantageous embodiment of the present invention is obtained.

When the two-channel amplifier with common signal comprises frequency dependent establishment of the common signal Z, an advantageous embodiment of the present invention is obtained.

When the two-channel amplifier with common signal comprises means for reducing high-frequency content of the common signal Z or the common output signal C, wherein high-frequency content comprises content above 500 Hz, more preferably above 1 kHz, more preferably above 4 kHz and most preferably above 20 kHz, an advantageous embodiment of the present invention is obtained.

When said splitter SPL comprises a frequency dependent algorithm for establishing the three intermediate signals X, Y, Z, an advantageous embodiment of the present invention is obtained.

The present invention further relates to a method of establishing a two-channel output with a common signal from a two-channel input, comprising splitting said two-channel input LI, RI into three intermediate signals X, Y, Z whereby one of said three intermediate signals Z is a common signal established at least partly on the basis of an addition of each signal of said two-channel input LI, RI.

By the present invention is obtained an advantageous method of converting a two-channel signal into a two-channel signal with a common signal being compatible with 3-wire connectors, e.g. stereo headphone jack plugs, etc. Several advantages as described above are obtained when basing the common signal on a sum of the signals from the two input channels.

When said method is carried out by a two-channel amplifier with common signal according to any of the above, an advantageous embodiment of the present invention is obtained.

It is noted, that any combination of features described above are within the scope of the present invention.

The present invention further relates to a stereo signal representation comprising three components X, Y, Z; a, b, c; A, B, C together representing two channels LI, RI, wherein a first of said three components is a common signal Z; C to said two channels and comprises a representation based on a sum of signals of said two channels.

According to the present invention is obtained an advantageous way of representing a stereo signal or other two-channel signal, which is particularly useful for devices with 3-wire outputs.

When said common signal Z; C comprises a representation of half an inverse sum of signals of said two channels LI, RI, an advantageous embodiment of the present invention is obtained.

When a second of said components X; A comprises a sum based on a signal of a first channel LI and said common signal Z; C, and a third of said components Y, B comprises a sum based on a signal of a second channel RI and said common signal Z; C, an advantageous embodiment of the present invention is obtained.

When said second component X; A comprises a signal corresponding to a sum of said common signal Z; C and a factor k times said first channel signal LI, and said third component Y, B comprises a signal corresponding to a sum of said common signal Z; C and said factor k times said second channel signal RI, an advantageous embodiment of the present invention is obtained.

When said factor k substantially equals 2, an advantageous embodiment of the present invention is obtained.

When said stereo signal representation comprises three positive-only components comprises a, b, c; A, B, C based on said three components X, Y, Z, an advantageous embodiment of the present invention is obtained.

When said three positive-only signals a, b, c; A, B, C comprise half a difference between said three components X, Y, Z and a minimum value LV across said three components X, Y, Z, respectively, an advantageous embodiment of the present invention is obtained.

When a clamping value MV is added to each of said three positive-only signals a, b, c; A, B, C, an advantageous embodiment of the present invention is obtained.

When soft limiting or adaptive limiting is applied to said three positive-only signals a, b, c; A, B, C, an advantageous embodiment of the present invention is obtained.

When the common signal Z; C comprises a frequency dependent representation based on a sum of signals of the two channels, an advantageous embodiment of the present invention is obtained.

The present invention further relates to a use of a two-channel amplifier with common signal according to any of the above in a consumer electronic product, preferably a portable audio and/or video device.

Using a two-channel amplifier with common signal according to the present invention in products with 3-wire audio outputs, which are extremely common for consumer electronics in particular, is extraordinarily useful and advantageous, as it aims at optimizing one of the key aspects in consumer electronics in general and portable devices in particular, namely the relationship between voltage supply and power output.

The present invention further relates to an audio processing device comprising a stereo signal representation according to any of the above.

Enabling use of a stereo signal representation according to any of the above in an audio processing device is extremely useful wherever 3-wire connectors are relevant, which they are in the vast majority of audio consumer electronics.

The present invention further relates to a two-channel amplifier comprising a three-terminal output A, B, C, said two-channel amplifier being arranged to provide via the three-terminal output two signals A, B and a common signal C being common to two channels LI, RI, facilitating providing a peak-peak voltage of a difference between one of the two signals A, B and the common signal C that is greater than a peak-peak supply voltage +Vcc; +Vcc, −Vcc used to drive said two-channel amplifier.

The present invention enables a peak-peak voltage greater than the peak-peak voltage of the power supply to be provided to a load. Thereby a highly advantageous relationship between supply voltage and power output is obtained.

When the peak-peak voltage of the difference is substantially twice the peak-peak supply voltage, an advantageous embodiment of the present invention is obtained.

When the two-channel amplifier comprises a two-channel amplifier with common signal according to any of the above, an advantageous embodiment of the present invention is obtained.

### BRIEF DESCRIPTION OF THE DRAWINGS

The invention will in the following be described with reference to the drawings where

FIG. 1 illustrates an embodiment of the present invention,

FIG. 2 illustrates a second embodiment of the present invention,

FIG. 3-6 illustrate signals occurring in a second embodiment of the invention and

FIG. 7-11 illustrate statistics related to a second embodiment of the invention.

### DETAILED DESCRIPTION

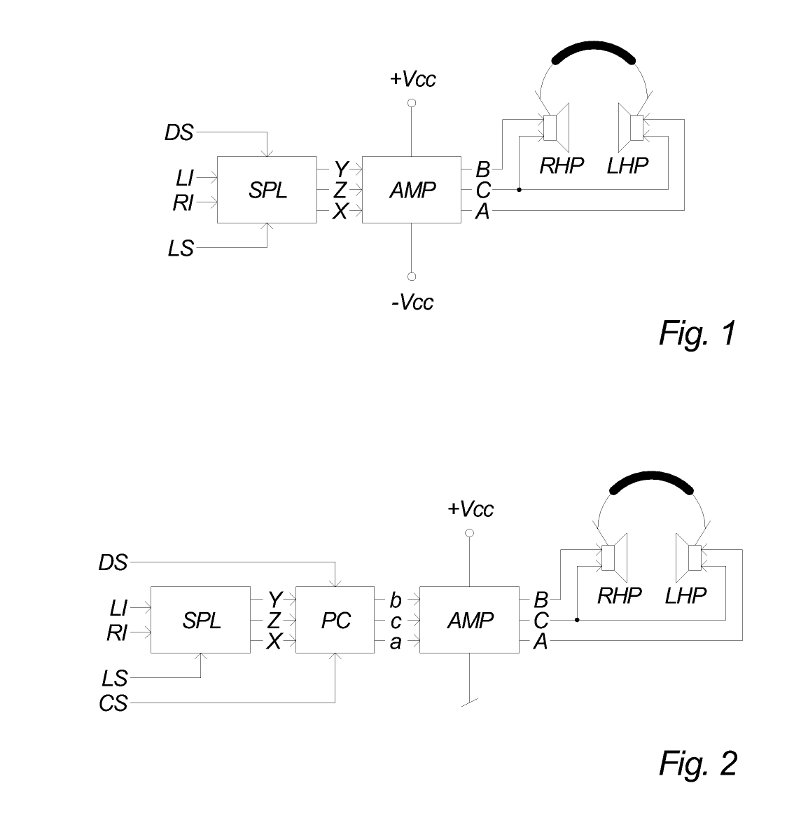

FIG. 1 illustrates a preferred embodiment of a two-channel amplifier according to the present invention. It comprises a left channel input signal LI and a right channel input signal RI, which are to be amplified suitable for reproduction in a conventional set of headphones comprising a left headphone LHP and a right RHP coupled to an amplifier block AMP by three wires, where a wire C is common to both of the headphones, and a wire A is specific for the left headphone LHP and a wire B is specific for the right headphone RHP. According to this conventional headphone configuration, the left headphone LHP will reproduce a difference of the signals on wires A and C, and the right headphone RHP will reproduce a difference of the signals on wires B and C, i.e.:

LHP=A−C

RHP=B−C

In order to deliver signals A, B and C that when rendered by the headphones according to the above will cause the intended audio signals, i.e. the left channel input signal LI and right channel input signal RI to be reproduced as sound, a splitter SPL is provided. The splitter takes the two audio channels LI and RI and map these two channels into three intermediate signals X, Y and Z which when amplified into signals A, B and C and combined by the headphones according to the above, results in sound that correspond to the two input channels plus gain. At the same time, the three intermediate signals X, Y and Z should be suitable for amplification with a gain g by an amplifier block AMP configured with three half-bridge amplifiers each having a gain g:

A=gX

B=gY

C=gZ

Combining the above to express the headphone output as functions of the intermediate signals gives:

LHP=g(X−Z)

RHP=g(Y−Z)

The mapping of the two input channels into the three intermediate signals can be made according to several different algorithms and coefficients. However, it can be shown from analyzing real music productions, that for a vast majority of stereo music information, the two channels are substantially in phase. This fact is even more significant when looking at the low frequency content, where the two channels in practically all audio productions are in phase. The low frequency content is also by far the most energy requiring content, where improved supply voltage efficiency really matters.

Hence, taking the above into consideration, a preferred embodiment of the present invention comprises a splitter SPL that establishes a common intermediate signal Z which carries information from both channels, i.e. a sum of LI and RI. Quite contrary to the known techniques mentioned above where a difference signal is used for the common wire, and which, as explained, approaches zero for most audio content and thereby not adds significantly to the efficiency, the sum signal according to the present invention will because of the in-phase nature of most stereo audio productions comprise a signal approximately twice the amplitude of any of the two input signals. The sum-signal is halved in order to normalize it, and to avoid clipping, and is inverted because it is delivered by the “negative” wire, i.e. subtracted by the headphones:

Z=−0.5(LI+RI)

Thereby is established an information carrying common signal which is quite active in the sense that its amplitude typically swings significantly more than any one of the two input signals. Spending amplification means, e.g. a half-bridge, on this common signal therefore significantly adds to the overall efficiency. In other words, the signal carried by Z resembles mono information where in-phase content is strengthened, completely off-phase content is removed, and uncorrelated content is simply carried on at half level.

The two other intermediate signals, X and Y, which are to be amplified and output as left and right headphone specific signals A and B, respectively, should comprise information which when rendered by the headphones and Z is subtracted, leads to reproduction of the input signals LI and RI.

Hence, in a preferred embodiment, such a mapping may comprise:

X=k·LI+Z=k·LI−0.5(LI+RI)=(k−0.5)LI−0.5·RI

Y=k·RI+Z=k·RI−0.5(LI+RI)=(k−0.5)RI−0.5·LI,

where k is a constant. In the headphones this renders as:

LHP=g(X−Z)=g(k·LI+Z−Z)=g·k·LI

RHP=g(Y−Z)=g(k·RI+Z−Z)=g·k·RI

The constant k boosts the channel specific input signal in order to elevate it from the half sum signal that is subtracted by the addition of Z. Referring to FIG. 1, the constant k is input to the splitter SPL by a level setting input LS. Obviously, a fixed value of k could be set in the splitter algorithm leaving the level setting input unnecessary, or the splitter or an external control block could dynamically adapt k according to the actual audio signal and present circumstances to always contain an optimal value. If k is 1, X and Y will for signals in phase approach zero, which does not lead to an efficient utilisation of the amplifiers for the same reasons by which the known techniques are not optimal. Hence, k should be greater than 1, and in a preferred embodiment of the present invention k is 2, leading to the following advantageous mapping into the intermediate signals X, Y and Z:

Z=−0.5(LI+RI)

X=2LI+Z=1.5·LI−0.5·RI

Y=2RI+Z=1.5·RI−0.5·LI

In other words, X comprises twice the left channel LI content plus the content of Z, in total 1.5 times the left channel LI and 0.5 times the right channel RI. Y comprises twice the right channel RI content plus the content of Z, in total 1.5 times the right channel RI and 0.5 times the left channel LI. For in-phase audio information, the signal level in X and Y will thus approach the level of any of these signals, and thereby require the associated amplifiers to process approximately the same audio energy as in a conventional non-differential approach with no signal on the common wire. As the signal Z is according to the present invention also carrying information and thereby also has to be amplified by a separate amplifier, and specifically for the present invention the level of Z in practice even approaches the input signal level instead of zero, the accumulated potential, i.e. voltage, delivered to each headphone is in practice twice compared to conventional amplifiers for three wire headphones with no information or amplification of the common wire signal. The voltage potential deliverable to the headphones in an embodiment of the present invention compared to a given supply voltage level thus resembles the possibilities and efficiency of a full-bridge double differential pair amplifier with potentially twice the potential as compared to a conventional stereo headphone amplifier. This is also clear from combining the above formulas from a preferred embodiment where k=2 into an expression for the headphone output as a function of the intermediate signals:

LHP=g(X−Z)=g(2LI+Z−Z)=2g·LI

RHP=g(Y−Z)=g(2RI+Z−Z)=2g·RI

Hence, the input channels LI and RI are reproduced correctly, at twice the gain g of each of the half-bridge amplifiers in the amplifier block AMP. The result thereby resembles a full bridge configuration allowing for potentially swings of twice the voltage supply at the output, i.e. 2g.

It is clear that other values are possible for the constant k within the scope of the present invention and within the restrictions mentioned above regarding k being 1. In order to achieve efficiency comparable to real DDP amplifiers, k should be 2 as explained above. In addition to the desired gain and efficiency, the value of k may be chosen according to characteristics of the actual audio signal, because some combinations of values k and audio signals may cause hard clipping of the audio signal within the splitter and/or amplifier. For example, in the most extreme case, an audio signal comprising completely opposite signals in the left and right channels at relatively high levels, e.g. peaks close to 1, e.g. LI=1 and RI=−1, will with k=2 cause peaks in the channel specific intermediate signals X and Y to approach 2 as e.g. X=1.5.1−0.5·(−1)=2. If the dynamics of the processing and amplifiers are not designed to handle this, and such overhead would typically not be considered cost-effective, the intermediate signals or the output signal will be clipped at e.g. 1. On the other hand, if the audio signal is in practice never close to full dynamic range, k could be chosen even greater, and thereby better utilise the dynamics available. In an embodiment of the present invention, k is therefore adaptive, and automatically adapts to the presently processed audio, like automatic gain control, preferably very slowly or rarely, e.g. only at the very beginning of a playback session.

In a preferred embodiment of the present invention illustrated in FIG. 1, the splitter SPL further comprises an input for dynamic settings DS. This allows for the splitter to apply e.g. compression and/or limiting to prevent signals from being hard clipped due to the above circumstances, as an alternative or in addition to changing k. By preventing clipping by controlled compression and/or limiting, the user experience will typically be far better.

As explained above, the amplifier block AMP of FIG. 1 preferably comprises three half-bridge amplifiers, i.e. single-ended output amplifiers. Actually, the present invention does not require any particular amplifier technology or configuration, as it will work with class-D amplifier configurations such as switching amplifiers and self-oscillating switching amplifiers, as well as more conventional amplifier configurations such as e.g. class-AB amplifiers, and with digital as well as analog amplifiers. In a preferred embodiment, the output impedances of the three amplifiers are as close to 0 Ohm as possible, in order to avoid errors, e.g. cross-talk due to the common amplifier used for the common signal C. Very low output impedance may in a preferred embodiment be obtained by feedback around each amplifier.

FIG. 2 illustrates an alternative, preferred embodiment of a two-channel amplifier according to the present invention. As the embodiment of FIG. 1, it comprises a left channel input signal LI and a right channel input signal RI, which are to be amplified suitable for reproduction in a conventional set of headphones comprising a left headphone LHP and a right RHP coupled to an amplifier block AMP by three wires, where a wire C is common to both of the headphones, and a wire A is specific for the left headphone LHP and a wire B is specific for the right headphone RHP. A splitter SPL is provided for establishing three intermediate signals X, Y and Z, e.g. according to the same principles and algorithms as described above regarding FIG. 1, i.e. in a preferred embodiment with k=2:

Z=−0.5(LI+RI)

X=2LI+Z=1.5−LI−0.5·RI

Y=2RI+Z=1.5·RI−0.5·LI

The two differences between the embodiments of FIG. 1 and FIG. 2 are that the amplifiers AMP in the embodiment of FIG. 2 are single-ended, typically with no negative potential but grounded instead, and that a separate processing block PC is added to process the intermediate signals X, Y and Z and establish pre-amplification signals a, b and c.

Often portable systems are powered by batteries and therefore use only a single positive supply voltage, instead of the differential supply shown in the embodiment of FIG. 1. The embodiment of the present invention illustrated in FIG. 2 enables use of the advantageous stereo headphone amplifier of the present invention also in such single-ended supply systems, e.g. MP3-players, etc. When the amplifiers are not able to reproduce negative signal values, the intermediate signals X, Y and Z have to be adapted into positive-only signals a, b and c. This is performed in the processing block PC.

In a preferred embodiment of the present invention, the algorithm utilized by the processing block for converting the intermediate signals into positive-only signals comprises subtracting the minimum value LV across the three intermediate signals X, Y and Z at any specific time, i.e. typically a negative value, from all three signals, causing all signals to be above zero due to the subtracting a negative value equals adding a positive value effect. The resulting signals are also halved in order to fit into the half dynamic range available in a single-ended amplifier. Expressing the above with formulas leads to:

LV=min([X Y Z])

a=0.5(X−LV)

b=0.5(Y−LV)

c=0.5(Z−LV)

The headphone output resulting from the above, when k=2, is:

LHP=g(a−c)=0.5g((X−LV)−(Z−LV))=0.5g((2LI+Z−LV)−(Z−LV))=g·LI

RHP=g(b−c)=0.5g((Y−LV)−(Z−LV))=0.5g((2RI+Z−LV)−(Z−LV))=g·RI

As is clear from the above, the halving performed in the processing block PC cancels the effect of the doubling performed in the splitter SPL when k=2. This, however, corresponds to what would be expected for a true DPP-amplifier with single-ended power supply. If a conventional headphone amplifier were used with single-ended power supply, the corresponding results would only be 0.5·g·LI and 0.5·g·RI, respectively.

For example, if at a certain time the left input signal LI is 0.6 and the right input signal RI is 0.7, the intermediate signals X, Y and Z will be:

Z=−0.5(LI+RI)=0.5(0.6+0.7)=−0.65

X=1.5·LI−0.5·RI=1.5·0.6−0.5·0.7=0.55

Y=1.5·RI−0.5·LI=1.5·0.7−0.5·0.6=0.75

The pre-amplification signals a, b and c will then be:

LV=min([X Y Z])=−0.65

a=0.5(X−LV)=0.5(0.55−(−0.65))=0.60

b=0.5(Y−LV)=0.5(0.75−(−0.65))=0.70

c=0.5(Z−LV)=0.5(−0.65−(−0.65))=0.00

And, just to verify, the output from the headphones will correspond to:

LHP=A−C=g(a−c)=g(0.60−0.00)=g·0.60

RHP=B−C=g(b·c)=g(0.70−0.00)=g·0.70

It is noted that even though the above algorithm for converting a set of double-sided signals into corresponding single-sided signals is preferred, any suitable algorithm for doing this is within the scope of the present invention, e.g. simply halving all signals and offsetting them by half the dynamic range, or any other method. The above-described algorithm brings, however, several advantages over simpler methods, as the resulting signals are biased relatively low instead of around the half supply voltage level. In particular, PWM amplifiers benefit from low biased signals.

In a preferred embodiment of the present invention, the processing block algorithm further adds a clamping value MV, preferably a small, constant value to the three intermediate signals in order to prevent potential nonlinearities in the amplifier AMP. For a class-D amplifier this could for example relate to minimum pulse width capabilities, i.e. the issue that switching amplifiers are not able to produce infinitely narrow pulses without distortion, and typically in such amplifiers, small signal values are modulated as narrow pulses. When using only single-sided signals, and because anything added in both X and Z or Y and Z, respectively, is cancelled by the subtracting behaviour of the reproduction in the headphones, there is no problem in adding a small amount to all three signals to get above the problematic range which may cause e.g. distorted narrow pulses or other non-linear distortion. A clamping value MV suitable for some amplifiers may e.g. be 0.05, or 5% of the dynamic range. If the amplifiers used require conversion into pulse width modulated PWM signals, e.g. class-D amplifiers, the clamping value may introduce distortion. This error is however known to the designer, e.g. that all signals are offset by 0.05, and can therefore be corrected by tuning the design of the PWM-converter.

It is noted, however, that any suitable clamping technique is within the scope of the present invention, including dynamic or adaptive techniques. For example, the processing block could be adapted to only add the clamping value MV when one or more of the signals gets into the problematic range, and otherwise not change the signals. The clamping value MV may be preset in the processing block, or the processing block may comprise an adaptive clamping value. Alternatively, the processing block may comprise a damper settings input CS for receiving a clamping value or settings for establishing a clamping value from an external control circuit or interface.

The formulas related to the processing block algorithm of a preferred embodiment of the present invention thus become:

LV=min([X Y Z])

MV=m (a constant)

a=0.5(X−LV)+MV

b=0.5(Y−LV)+MV

c=0.5(Z−LV)+MV

LHP=g(a−c)=g(0.5(2LI+Z−LV)+MV−(0.5(Z−LV)+MV))=g·LI

RHP=g(b−c)=g(0.5(2RI+Z−LV)+MV−(0.5(Z−LV)+MV))=g·RI

As with the embodiment of FIG. 1, other values are possible for the constant k within the scope of the present invention and the embodiment of FIG. 2, and within the same restrictions and particularities described above regarding FIG. 1.

Also as with the embodiment of FIG. 1, the dynamics may preferably by tuned e.g. in order to handle clipping e.g. due to the value k or the clamping value MV. In the embodiment of FIG. 2 the processing block PC comprises a dynamics settings input DS. This allows for the splitter to apply e.g. compression and/or limiting to prevent signals from being hard clipped due to the above circumstances, as an alternative or in addition to changing k or MV. By preventing clipping by controlled compression and/or limiting, the user experience will typically be far better. The dynamic settings input could also be applied to the splitter SPL as in the embodiment of FIG. 1, or to both, or the functionality could be implemented in processing block.

The amplifier block AMP of FIG. 2 may comprise any of the amplification means described above with reference to FIG. 1, with the difference of double-sided vs. single-sided power supply applied where necessary.

It is noted that the division into blocks, e.g. a splitter block SPL and a processing block PC, is not a requirement for the invention, and any distribution or gathering of the individual components and steps are within the scope of the present invention.

For example, it is possible to collapse the equations for the splitting block and the processing block into one set of equations establishing the amplification-ready signals a, b and c directly from the inputs LI and RI. What approach is most optimal for a given application depends on the specific implementation, e.g. the type of processing means available, compatibility issues, acceptable power consumption, etc.

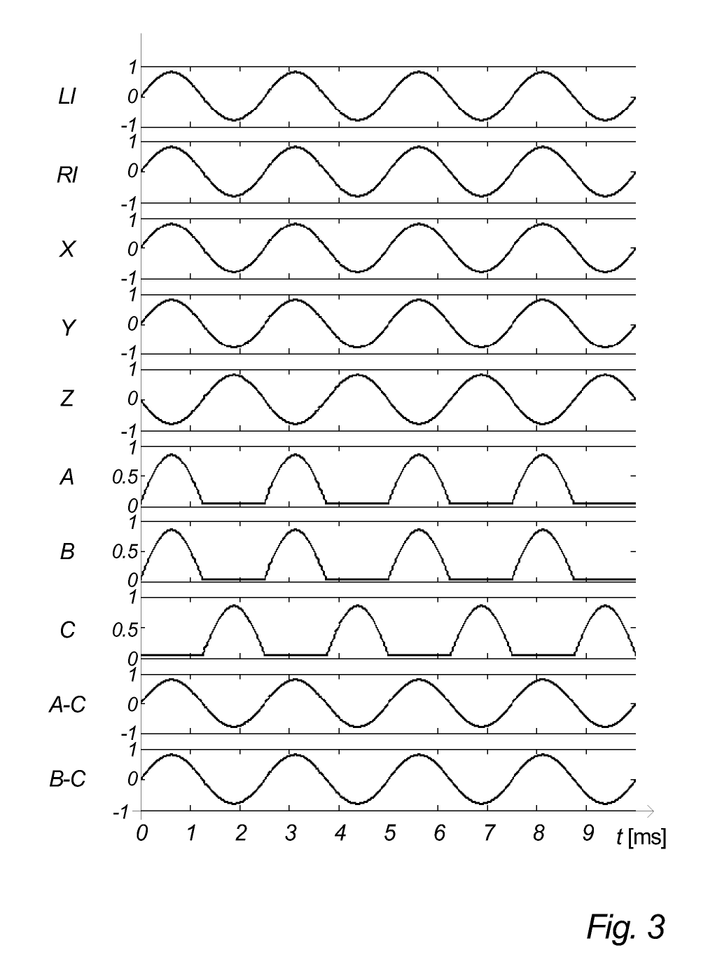

FIG. 3-6 illustrate different signals occurring in a preferred embodiment according to FIG. 2 and the above description in an embodiment where the factor k mentioned above is 2. All graphs comprise a horizontal axis representing time, in these examples 10 ms from left to right. The vertical axis in all graphs represents amplitude, but comprises several different signals. From the top, the first two signals are the left input LI and right input RI. In all the examples, these signals are for the sake of simplicity sine waves, but evidently any signal type, preferably audio, can be used. In the different drawings the relationship between the left and right input LI, RI, is different, and the result of different relationships are illustrated by the other signals. The next three signals are the intermediate signals X, Y and Z established by the splitter SPL. According to the present invention, X corresponds mostly with the left input LI subtracted by a little of the right input RI, and the opposite for Y. Z corresponds with an inverted, halved sum of the left and right input. The next three signals are the amplified signals A, B and C, i.e. corresponding to X, Y and Z, respectively, but converted to positive-only signals and with a clamping value added. The bottom two signals correspond to the output of the headphones, i.e. A-C and B-C, respectively. This is just to verify that the headphone output corresponds to the input, i.e. left and right input.

FIG. 3 illustrates a situation where two equal signals are provided by left input LI and right input RI, i.e. completely in-phase signals. Because the signals are equal, also X and Y are equal, and Z is an inverted version of any of the signals. Again, because the signals are equal, A and B are equal and comprises all positive half-periods of the signals, and C is inversed and comprises all negative half-periods of the signals. Note the offset from zero caused by the added clamping value. A-C and B-C correspond to LI and RI, respectively.

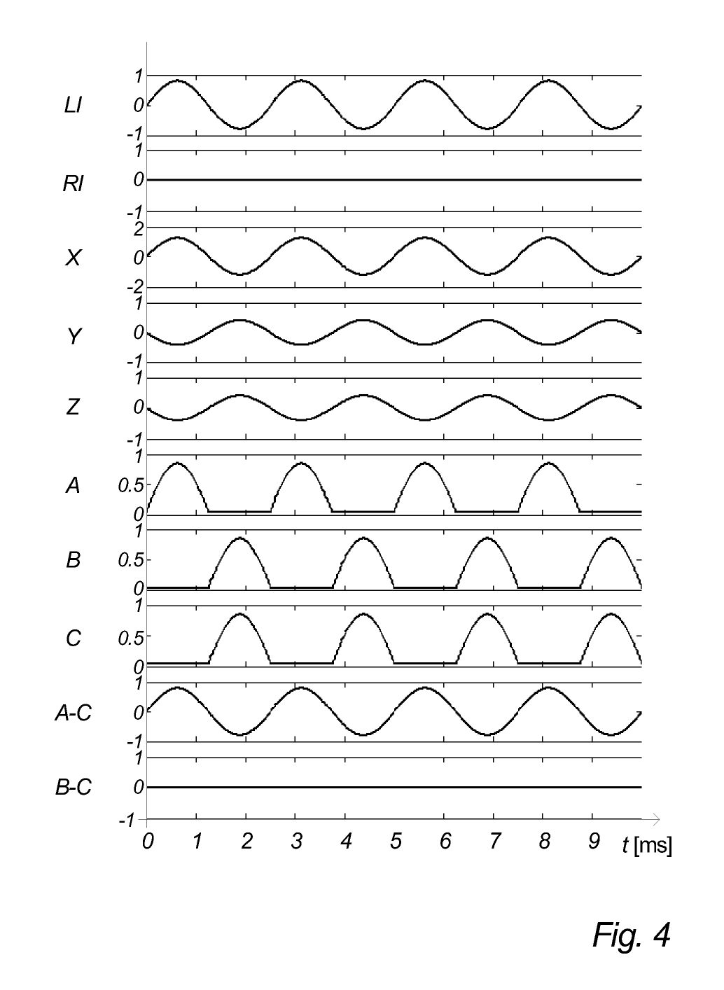

FIG. 4 illustrates a situation where the same signal as in FIG. 3 is provided by left input LI, but the right input RI is silent, i.e. equals zero all the time. In this situation the intermediate signal X corresponds to 1.5 times LI because of the silent RI, and thus exceeds the values 1 and −1 for a while in each top and bottom. Y comprises 0.5 times an inverted LI, because its main contributor RI is silent. Z being the inverse half sum of LI and RI thus corresponds to the inverse of the half of LI, which because the factor k in this example is 2, also corresponds to Y. Because of Y and Z being equal, A comprises all positive half-periods of LI, and B and C comprises all negative half-periods of LI. Even though X is above 1 or below −1 at several occasions, the mapping to the signal A results in, which is below 1 all the time, results in no clipping problems as long as the, preferably digital, processing means handling the intermediate signal X accepts a broader dynamic range. The headphone outputs A-C and B-C correspond to LI and RI, respectively.

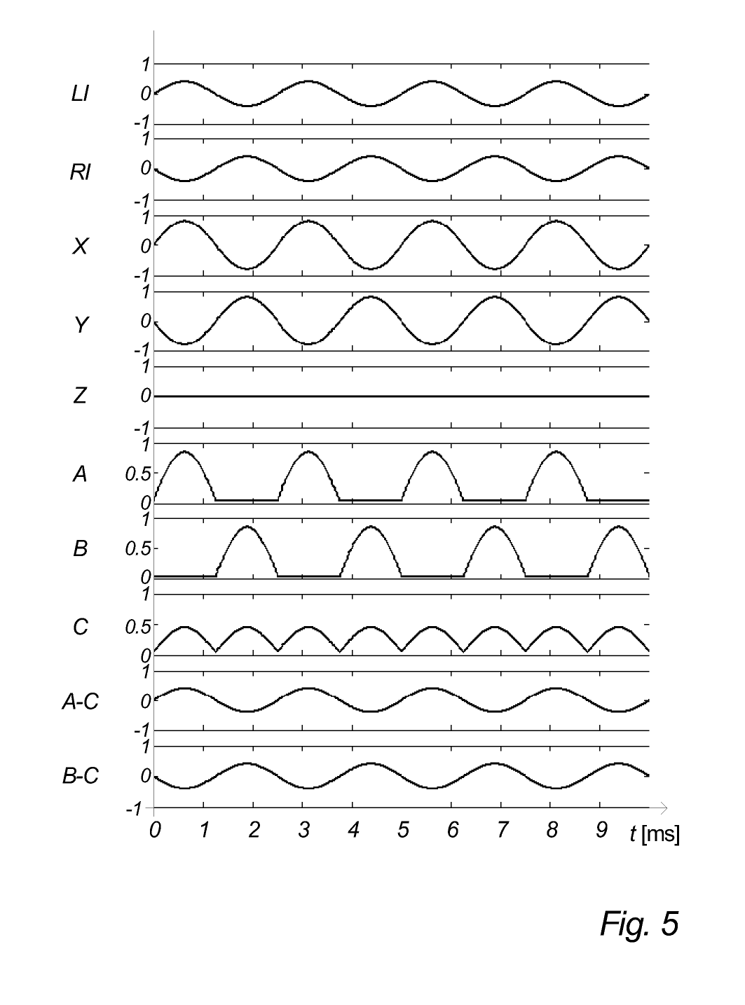

FIG. 5 illustrates a situation where two equal signals with opposite phases are provided by the inputs LI and RI. As described above, clipping is a problem when the phases are different, or actually, whenever one channel comprises positive value relatively far away from zero, while the other channel comprises a negative value relatively far away from zero. In order to avoid clipping, the input signals are therefore only half of the input signals used in the first two examples. In this situation the intermediate signals X and Y corresponds to 2 times LI and RI, respectively, and are thus 1 and −1 at their minima and maxima. Z becomes zero because it represents the sum of LI and RI. As with the in-phase example of FIG. 3 A and B gets to comprise the positive and negative half-periods respectively, but scaled to the double compared to the input amplitudes. In this case clipping would obviously have occurred if the input signals had been full-scale signals. C comprises a kind of ripple-signal as it comprises an inversion of all negative half-periods of either X and Y, at half amplitude. The headphone outputs A-C and B-C correspond to LI and RI, respectively, but only because the input signals have restricted levels. If completely opposite-phase full-scale signals had been used, a heavy degree of clipping would have occurred, resulting in distortion of the headphone outputs.

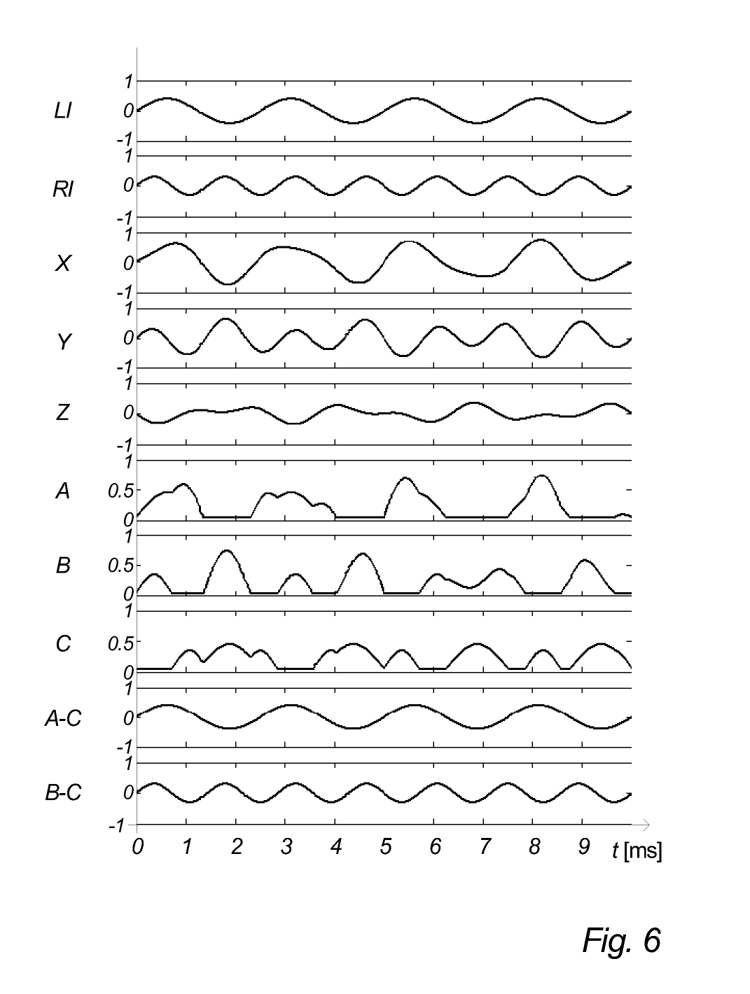

FIG. 6 illustrates a situation where two uncorrelated sine waves signals, i.e. with different periodicity, are provided by the inputs LI and RI. In order to avoid clipping, the input signals are again only half of full scale. X and Y comprising a main part of LI and RI, respectively, and a small part of the opposite channel, get to be sort of LI modulated with RI, and RI modulated with LI, respectively. Z is a sum signal of LI and RI, and is therefore close to zero when LI and RI are opposite and relatively high-levelled when LI and RI follow each other. A, B and C are rather complex signals, and due to the input signals being only half-scale, no clipping occurs. The headphone outputs A-C and B-C correspond to LI and RI, respectively, but only because the input signals have restricted levels.

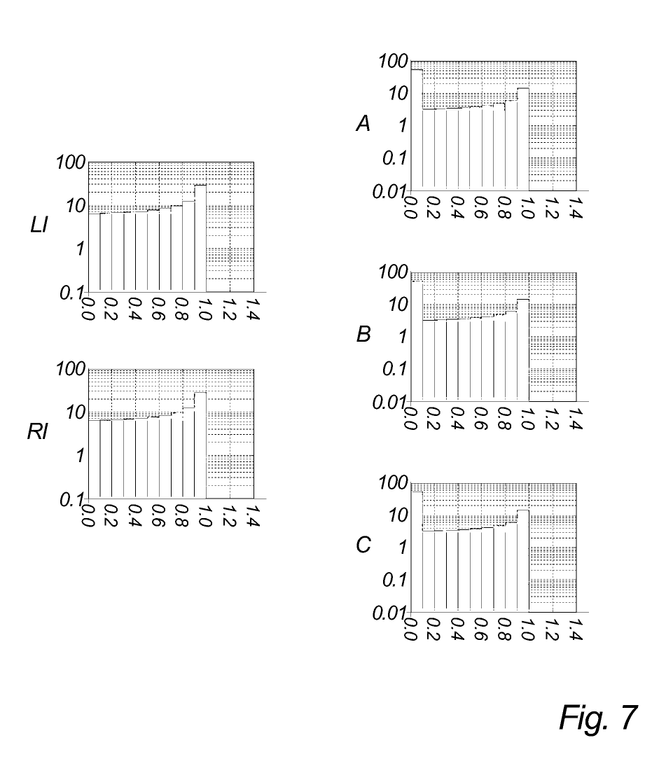

As seen from FIG. 3-6 the principles of the present invention also work in simulations. Clipping will, as also acknowledged above, however occur whenever the difference of two relatively large-scale input channels is large, i.e. most of the time for completely opposite signals and relatively often for uncorrelated signals, but on the other hand never for mono signals or completely in-phase signals. As explained above, in real world music most of the energy conveys low-frequency information which is typically in-phase, and less energy is used for uncorrelated information at higher audio frequencies. Hence it could be expected that typical music would lead to only a small amount of clipping, as high-level signals are in-phase, and therefore do not clip, and the possibly uncorrelated treble information is present only at lower, unproblematic levels. This is investigated further as described below with reference to FIG. 7-11.

FIG. 7-11 illustrate histograms of the absolute level of various input signals LI and RI, and the resulting amplified signals A, B and C, when processed by simulation of an embodiment of the present invention according to FIG. 2 as described above. In order to investigate the degree of clipping, the simulation allows levels above 1.0, which would actually clip in a real implementation. All horizontal axes represent absolute level and the vertical axes represent percentage of samples, and the diagrams therefore illustrate the amplitude distribution, or in other words, the degree to which different levels are present in the signal. Note, that the vertical axes have logarithmic scales. For example, in FIG. 7 at the graph representing the distribution in the signal LI, it can be seen that approximately 7% of the samples have levels between 0.4 and 0.5, and approximately 28% of the samples have levels between 0.9 and 1.0.

FIG. 7 comprises histograms for input signals LI and RI comprising two equal sine waves completely in-phase. The histograms for LI and RI show that the signals comprise a high degree of high-level samples, which would also be expected as the sine wave only changes slowly at its maxima and minima It can also be seen that the amplified signals A, B and C comprise no levels above 1, i.e. no overloads that would clip in a real implementation. The result illustrated by FIG. 7 corresponds with FIG. 3, which also illustrate two equal in-phase sine waves.

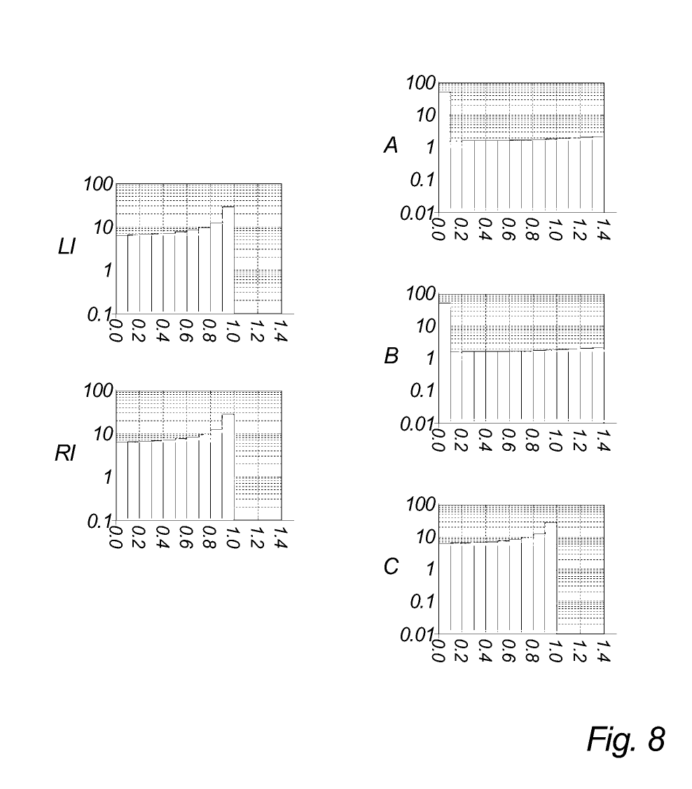

FIG. 8 comprises histograms for input signals LI and RI comprising two equal, but completely opposite, sine waves, i.e. having completely opposite phases. This corresponds to FIG. 5 above, except that full-scale signals are used in FIG. 8. As phase-information does not show in the histograms, the distributions for LI and RI equals those of FIG. 7. Because of the opposite phases, the resulting distributions for A, B and C are quite different, however. Evidently A and B comprise many overloads, i.e. levels above 1.0, which would probably cause clipping in a real implementation. This result is also expected from the above, theoretical description.

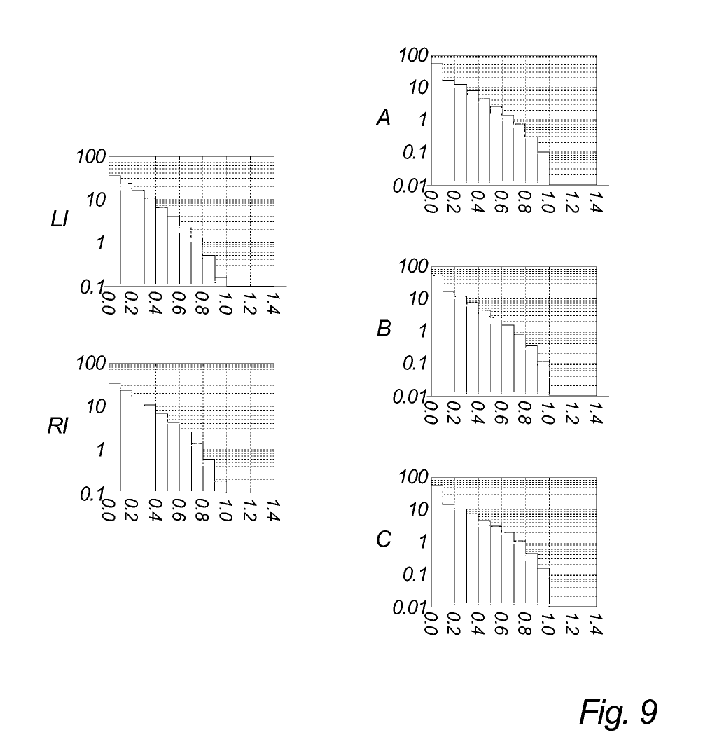

The above-described FIGS. 7 and 8 illustrates two extremes, i.e. completely in-phase signals which never cause overload and completely opposite signals which cause a maximum amount of overload when processed by an algorithm according to an embodiment of the present invention. The following description relating to FIG. 9-11 illustrates possible results when processing real-world audio.

FIG. 9 comprises histograms for input signals LI and RI comprising the left and right channels of the entire CD audio track of “Hung Up” from Madonna's “Confessions on a Dance Floor”. As seen, the audio track signals comprise levels less than 0.1 more than 30% of the time, and less than 0.4 approximately 80% of the time. High levels above 0.8 are present for less than 0.8% of the time, hereof approaching the limit, i.e. between 0.9 and 1.0, less than 0.2% of the time. Already because of the little amount of high levels, it can be expected that overload will only be a very limited problem, even though phase difference do not show in the histograms.

Looking at the output signal histograms reveals that no overload occurs, i.e. no levels above 1.0 are present in any of the three output signals A, B and C, at least not more than 0.01% of the time. Hence, the algorithm is able to process this particular audio track without quality degradation, even at full volume setting.

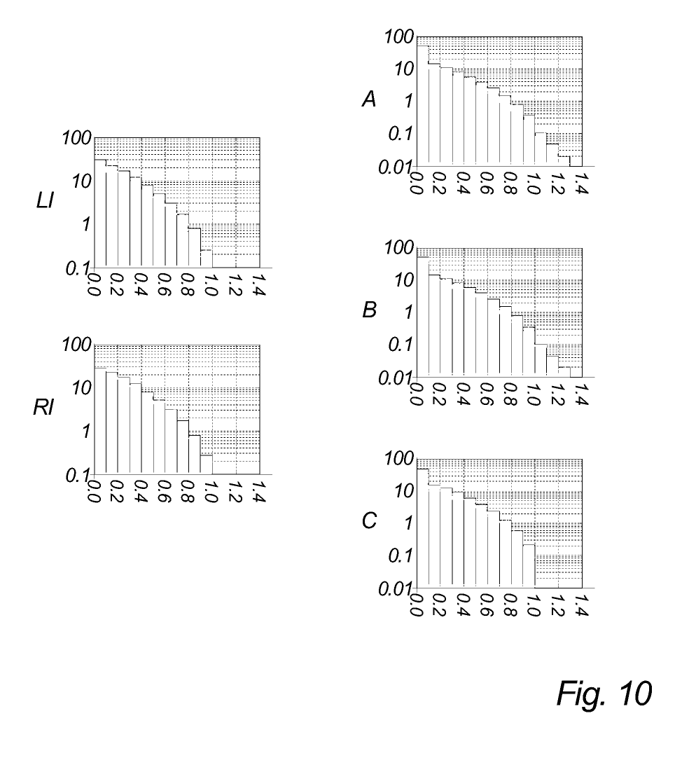

FIG. 10 comprises histograms for input signals LI and RI comprising the left and right channels of the entire CD audio track of “Get Together”, again from Madonna's “Confessions on a Dance Floor”. As seen, the audio track signals again comprise levels less than 0.1 more than 30% of the time, and less than 0.4 approximately 80% of the time. High levels above 0.8 are present for approximately 1% of the time, hereof approaching the limit, i.e. between 0.9 and 1.0, approximately 0.25% of the time. Looking at the output signal histograms reveals that some degree of overload occurs in signals A and B, but not in signal C. Approximately 0.17% of the output samples have levels above 1.0, and of these are approximately 0.02% above the level 1.2. Hence, the algorithm alone will not be able to process this particular audio track without causing clipping at full volume settings for a very few samples.

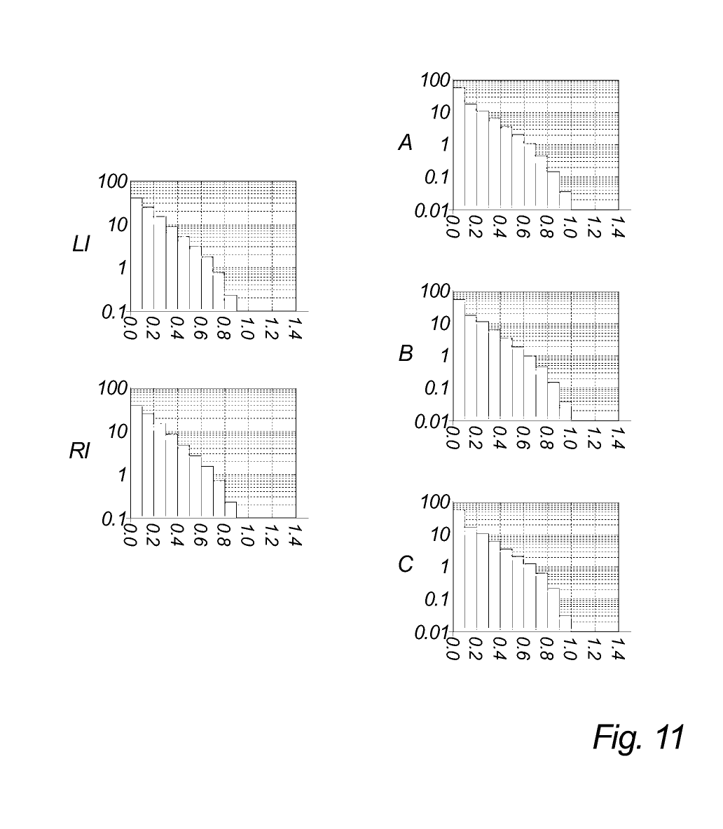

FIG. 11 comprises histograms for input signals LI and RI comprising the left and right channels of the entire CD audio track of “Forbidden Love”, again from Madonna's “Confessions on a Dance Floor”. As seen, the audio track signals again comprise levels less than 0.1 approximately 40% of the time, and less than 0.4 close to 90% of the time. High levels above 0.8 are present for only approximately 0.2% of the time, hereof approaching the limit, i.e. between 0.9 and 1.0, none or at least less than 0.1% of the time. The present audio track therefore comprises less high levels than the two above-described tracks. Looking at the output signal histograms reveals that no overload occurs, i.e. no levels above 1.0 are present in any of the three output signals A, B and C, at least not more than 0.01% of the time. Hence, the algorithm is able to process this particular audio track without quality degradation, even at full volume setting.

Of course the three examples above are not sufficient statistical basis to state anything with statistical significance, but they illustrate quite well the results obtained when making similar investigations on a lot of audio tracks. The conclusion from the above experiment, which included several further audio tracks than described above in this patent application, is that when processing popular music produced and mixed using standard procedures, i.e. with no looking ahead to accommodate the algorithm of the present invention, even with quite aggressively mastered music as this Madonna CD, clip problems will only occur from between approximately −2 dBFS to −1 dBFS, i.e. levels above approximately 0.8. So even without any dynamic processing and only not using the top of the range, the principles of the present invention even in this situation have approximately 4 dB level advantage, i.e. 6 dB from double voltage swing minus 2 dB from unusable dynamic range, which is still more than double the power compared to ordinary headphone amplifiers. It is noted again, that the above applies to extremely high volume settings, i.e. full volume. For smaller input signals, i.e. having lower volume level, the overload problem is completely insignificant, and the present invention amplifies sound without audio quality degradation.

In a preferred embodiment of the present invention, a simple adaptive limiting is applied to handle the very few overloads, i.e. typically far less than 0.1%, without any audio quality degradation.

It is noted, that the scope of the present invention is broader than the specific embodiments described above, for example is any combination of the above-described features within the scope of the present invention.

Moreover, additional processing may be arranged anywhere in the system. For example, in a preferred embodiment of the present invention based on switching power stages and pulse modulated signals, such additional processing may e.g. comprise an algorithm for avoiding substantially concurrent pulse edges in any two or three of the three switching amplifiers, in order to avoid the switching of one amplifier to disturb the switching of another. Such processing may be performed within the pulse modulator of the amplifier, e.g. by relocating some of the pulses, or prior to the modulation, e.g. within the splitter or the processing block, e.g. by shaping the signals to not produce concurrent pulses when modulated. Such pre-shaping of the signals may e.g. be performed by adding a preferably level-controlled outband signal to the utility signals or by remapping problematic signal values within a noise-shaper loop. Detailed description of such techniques suitable for use with the present invention can be found in the International patent application publication No. WO 2005/117253 A1, hereby incorporated by reference.

Also problems related with cross-talk and EMC can by reduced or avoided by additional processing or circuitry within the scope of the present invention. Several kinds of headphone cables and other 3-wire stereo cables use the common conductor also as electromagnetic shielding, e.g. a woven sleeve of metal threads. In some devices, e.g. some mobile phones, the common conductor of the headset is even arranged to also work as an antenna for FM radio reception. When a signal is applied to the common conductor e.g. according to the present invention, the nature of the shielding or antenna kind of common conductor may cause unacceptable or undesired electromagnetic emission. This problem can be reduced within the scope of the present invention by reducing the activity in the common signal, in particular with regard to high frequencies. In an embodiment comprising pulse modulated switching amplifiers, the outputs A, B and C are typically pulsed signals, e.g. PWM signals, and therefore comprise high frequency content far above the audio band. In a simple embodiment a low-pass filter could be applied to the common signal in order to reduce the high frequency content before transmitted through the cable to the headphone. In an alternative embodiment, the amplifier used for the common signal is an analog amplifier type, e.g. a class-AB amplifier, even when the amplifiers for the individual signals A and B are class-D amplifiers, as the present invention does not require using equal amplifiers or amplifier techniques for all three signals.

Even content in the upper part of the audio band may produce problematic emissions from the common signal conductor. This problem can, however, also be solved within the scope of the present invention as it is regarding amplification of the lower frequency content the present invention really provides great benefit, as described above. Hence, there is actually no need to necessarily applying the splitting of signals according to the present invention above some frequency determined on an application-by-application basis according to the expected kind of audio signals, the degree of problems according to EMC, etc. Therefore, in a preferred embodiment of the present invention, the splitter comprises means for performing the splitting only on low frequency content, e.g. below 500 Hz, 1 kHz, 4 kHz or another relevant threshold. The higher frequency content should simply be forwarded to the intermediate signals X and Y unchanged. The frequency threshold may be a hard threshold, or it may comprise a gradual change. This may e.g. be accomplished by letting the formulas described above for the splitter algorithm be frequency dependent, band width limited, or use different formulas for different frequency bands. Hence, if the formula for the intermediate, common signal Z is made dependent on frequency in the sense that Z becomes e.g. the half of the inversed sum of LI and RI only for frequencies below 1 kHz of these signals, and otherwise simply becomes zero, and the formulas for the signals X and Y are unchanged so that the frequency dependent Z is added, the result will be that high frequency content from LI is forwarded unchanged by signal X, high frequency content from RI is forwarded unchanged by signal Y, and low frequency content is split as described in detail above, e.g. with regard to FIGS. 1 and 2. In an alternative embodiment a low-pass filter is applied as part of the signal Z formula. In yet an alternative embodiment a frequency splitter is applied before the signal splitter SPL so that high frequency content circumvents the signal splitter SPL and is added to the X and Y signals afterwards, whereas low frequency content is provided for the signal splitter SPL. By limiting the frequency content of the common signal C is provided a two-channel amplifier with a common signal, where the common signal is however only active when necessary in order to benefit from the power advantages according to the present invention. At times with no need for extra voltage swing, e.g. with only low volume or substantially no low-frequency content of significance, the common signal is substantially inactive and therefore represents no EMC problems.

1. A two-channel amplifier with common signal comprising:
a splitter for establishing three intermediate signals on a basis of two input signals,
wherein said three intermediate signals represent two channels, one of said three intermediate signals being a common signal common to both of said two channels and comprising a representation based on a sum of said two input signals.

2. The two-channel amplifier with common signal according to claim 1, comprising two inputs for receiving said two input signals, three outputs for providing three output signals and an amplifier block for establishing said three output signals on the basis of said three intermediate signals.

3. The two-channel amplifier with common signal according to claim 2, wherein said amplifier block comprises three single-ended output amplifiers.

4. The two-channel amplifier with common signal according to claim 2, wherein said amplifier block is driven by a double-sided power supply.

5. The two-channel amplifier with common signal according to claim 2, wherein said amplifier block is driven by a single-sided power supply.

6. The two-channel amplifier with common signal according to claim 1, comprising a level setting input.

7. The two-channel amplifier with common signal according to claim 1, comprising a dynamic setting input.

8. The two-channel amplifier with common signal according to claim 1, wherein said two input signals represent a left channel and a right channel, respectively, of a stereo audio signal.

9. The two-channel amplifier with common signal according to claim 2, wherein said three outputs are arranged for connecting two loads by connecting one of said three output signals being a common output signal common to both of said two channels to both of said two loads, and connecting each of other two of said three output signals to corresponding ones of said two loads, respectively.

10. The two-channel amplifier with common signal according to claim 1, wherein said common signal comprises a representation of half an inverse sum of said two input signals.

11. The two-channel amplifier with common signal according to claim 1, wherein a second of said three intermediate signals comprises a sum based on a first of said two input signals and said common signal, and a third of said three intermediate signals comprises a sum based on a second of said two input signals and said common signal.

12. The two-channel amplifier with common signal according to claim 1, wherein said second of said three intermediate signals comprises a signal corresponding to a sum of said common signal and a factor times a first of said two input signals, and said third of said three intermediate signals comprises a signal corresponding to a sum of said common signal and said factor times a second of said two input signals.

13. The two-channel amplifier with common signal according to claim 12, wherein said factor substantially equals 2.

14. The two-channel amplifier with common signal according to claim 12, wherein said factor is controlled by said level setting input.

15. The two-channel amplifier with common signal according to claim 1, wherein adaptive limiting or soft limiting is applied to said three intermediate signals.

16. The two-channel amplifier with common signal according to claim 15, wherein said limiting is controlled by said dynamic setting input.

17. The two-channel amplifier with common signal according to claim 1, comprising a processing block adapting said three intermediate signals into three positive only signals.

18. The two-channel amplifier with common signal according to claim 17, wherein said three positive-only signals comprise half the differences between said three intermediate signals and a minimum value across said three intermediate signals, respectively.

19. The two-channel amplifier with common signal according to claim 17, wherein a clamping value is added to each of said three positive-only signals.

20. The two-channel amplifier with common signal according to claim 19, comprising a clamper setting input controlling said clamping value.

21. The two-channel amplifier with common signal according to claim 17, wherein soft limiting or adaptive limiting is applied to said three positive-only signals.

22. The two-channel amplifier with common signal according to claim 21, comprising a dynamics setting input controlling said limiting.

23. The two-channel amplifier with common signal according to claim 1, comprising an input for a single-sided power supply.

24. The two-channel amplifier with common signal according to claim 1, comprising an input for a double-sided power supply.

25. The two-channel amplifier with common signal according to claim 1, comprising a processor arranged to avoiding substantially concurrent edges of pulse width modulated signals.

26. The two-channel amplifier with common signal according to claim 1, comprising frequency dependent establishment of the common signal.

27. The two-channel amplifier with common signal according to claim 1, reducing high-frequency content of the common signal or the common output signal, wherein high-frequency content comprises content above 500 Hz.

28. The two-channel amplifier with common signal according to claim 1, wherein said splitter comprises a frequency dependent algorithm for establishing the three intermediate signals.

29. A method of establishing a two-channel output with a common signal from a two-channel input, comprising splitting said two-channel input into three intermediate signals whereby one of said three intermediate signals is a common signal established at least partly on the basis of an addition of each signal of said two-channel input.

30. The method of establishing a two-channel output with a common signal from a two-channel input according to claim 29, whereby said method is carried out by a two-channel amplifier with common signal comprising a splitter for establishing three intermediate signals on the basis of two input signals, wherein said three intermediate signals re resent two channels one of said three intermediate signals being a common signal common to both of said two channels and comprising a representation based on a sum of said two input signals.

31. A stereo signal representation comprising three components together representing two channels, wherein a first of said three components is a common signal to said two channels and comprises a representation based on a sum of signals of said two channels.

32. The stereo signal representation according to claim 31, wherein said common signal comprises a representation of half an inverse sum of signals of said two channels.

33. The stereo signal representation according to claim 31, wherein a second of said components comprises a sum based on a signal of a first channel and said common signal, and a third of said components comprises a sum based on a signal of a second channel and said common signal.

34. The stereo signal representation according to claim 31, wherein said second component comprises a signal corresponding to a sum of said common signal and a factor times said first channel signal, and said third component comprises a signal corresponding to a sum of said common signal and said factor times said second channel signal.

35. The stereo signal representation according to claim 34, wherein said factor substantially equals 2.

36. The stereo signal representation according to claim 31, wherein said stereo signal representation comprises three positive-only components based on said three components.

37. The stereo signal representation according to claim 36, wherein said three positive-only signals comprise half a difference between said three components and a minimum value across said three components, respectively.

38. The stereo signal representation according to claim 36, wherein a clamping value is added to each of said three positive-only signals.

39. The stereo signal representation according to claim 36, wherein soft limiting or adaptive limiting is applied to said three positive-only signals.

40. The stereo signal representation comprising according to claim 31, wherein the common signal comprises a frequency dependent representation based on a sum of signals of the two channels.

41. (canceled)

42. An audio processing device comprising a stereo signal representation comprising three components together representing two channels, wherein a first of said three components is a common signal to said two channels and comprises a representation based on a sum of signals of said two channels.

43. A two-channel amplifier comprising a three-terminal output, said two-channel amplifier being arranged to provide via the three-terminal output two signals and a common signal being common to two channels, facilitating providing a peak-peak voltage of a difference between one of the two signals and the common signal that is greater than a peak-peak supply voltage used to drive said two-channel amplifier.

44. The two-channel amplifier according to claim 43, wherein the peak-peak voltage of the difference is substantially twice the peak-peak supply voltage.

45. The two-channel amplifier according to claim 43, comprising a two-channel amplifier with common signal comprising a splitter for establishing three intermediate signals on the basis of two input signals, wherein said three intermediate signals represent two channels, one of said three intermediate signals being a common signal common to both of said two channels and comprising a representation based on a sum of said two input signals.

46. The two-channel amplifier with common signal according to claim 9, wherein said two loads comprises a stereo headphone.

47. The two-channel amplifier with common signal according to claim 23, wherein said single-sided power supply comprises a battery.

48. The two-channel amplifier with common signal according to claim 27, wherein high-frequency content comprises content above 20 kHz.
